(19) United States
(12) Patent Application Publication
(10) Pub. No.: US 2026/0363046 A1
(43) Pub. Date: Nov. 12, 2026

(54) ACTIVE INTERPOSER STRUCTURE AND MANUFACTURING METHOD THEREOF, AND 3D IC PACKAGE

(71) Applicant: Powerchip Semiconductor Manufacturing Corporation, Hsinchu (TW)

(72) Inventors: Shou-Zen Chang, Hsinchu City (TW); Ling Yen Yeh, Hsinchu (TW); Hsien Wei Wang, Hsinchu (TW); Hiroshi Yoshida, Hsinchu City (TW); Kuo-Chang Huang, Hsinchu (TW)

(73) Assignee: Powerchip Semiconductor Manufacturing Corporation, Hsinchu (TW)

(21) Appl. No.: 19/201,839

(22) Filed: May 7, 2025

(51) Int. Cl. H10W 20/20; H10W 20/43; H10W 72/20; H10W 90/00

(52) U.S. Cl. CPC H10W 20/20; H10W 20/43; H10W 90/00; H10W 72/20

(57) ABSTRACT

An active interposer structure includes a silicon substrate, a first transistor, at least one second transistor and a plurality of micro-bumps (μbumps). The silicon substrate has a first surface and a second surface opposite to the first surface. The first transistor is formed on the first surface of the silicon substrate. The second transistor is formed over the first transistor, wherein the second transistor is different from the first transistor. The micro-bumps are formed over the second transistor and electrically connected to the first transistor and the second transistor. A 3D IC package includes above active interposer structure and semiconductor dies, wherein the semiconductor dies are bonded to the active interposer structure through the micro-bumps.

### BACKGROUND

### Technical Field

The disclosure relates to a semiconductor manufacture technique, and particularly relates to an active interposer structure and a manufacturing method thereof, and a 3D integrated circuit (IC) package.

### Description of Related Art

3D stacked integrated package has become future direction of the semiconductor development. There is an ongoing need to improve the property and performance of the 3D stacked integrated package.

### SUMMARY

The active interposer structure of one embodiment of the disclosure includes a silicon substrate, a first transistor, at least one second transistor and a plurality of micro-bumps (μbumps). The silicon substrate has a first surface and a second surface opposite to the first surface. The first transistor is formed on the first surface of the silicon substrate. The second transistor is formed over the first transistor, wherein the second transistor is different from the first transistor. The micro-bumps are formed over the second transistor and electrically connected to the first transistor and the second transistor.

In one embodiment of the disclosure, the active interposer structure further includes back-end-of-line (BEOL) structure disposed between the plurality of micro-bumps and the silicon substrate for connecting the first transistor and the at least one second transistor to the plurality of micro-bumps.

In one embodiment of the disclosure, the active interposer structure further includes a plurality of through-silicon vias (TSVs) passing through the silicon substrate.

In one embodiment of the disclosure, the active interposer structure further includes a passive device formed over the at least one second transistor.

In one embodiment of the disclosure, the passive device comprises a capacitor, a resistor, or an inductor.

In one embodiment of the disclosure, the active interposer structure further includes connection structure, a plurality of interposer pads, and a plurality of interposer bumps. The connection structure is formed on the second surface of the silicon substrate. The interposer pads are disposed on the connection structure. The interposer bumps are formed on the interposer pads.

The manufacturing method of an active interposer structure of another embodiment of the disclosure includes following steps. A first transistor is formed on a first surface of a silicon substrate, at least one second transistor is formed over the first transistor, and a plurality of micro-bumps is formed over the at least one second transistor for coupling to the first transistor and the at least one second transistor.

In another embodiment of the disclosure, before forming the micro-bumps, the method further includes forming a BEOL structure on the silicon substrate for connecting the first transistor or the second transistor.

In another embodiment of the disclosure, the first transistor and the second transistor are coupled to the micro-bumps through the BEOL structure.

In another embodiment of the disclosure, after forming the micro-bumps, the method further includes forming a passive device over the at least one second transistor.

In another embodiment of the disclosure, before forming the second transistor, the method further includes forming a through-silicon vias passing through the silicon substrate.

In another embodiment of the disclosure, after forming the micro-bumps, the method further includes forming a connection structure on a second surface of the silicon substrate, wherein the second surface is opposite to the first surface; forming a plurality of interposer pads on the connection structure; and forming a plurality of interposer bumps on the plurality of interposer pads.

In above embodiments of the disclosure, the first transistor includes a silicon FET, and the second transistor includes a semiconductor layer containing an oxide semiconductor (OS).

The 3D IC package of yet another embodiment of the disclosure includes above active interposer structure and a plurality of semiconductor dies. The semiconductor dies are bonded to the active interposer structure through the micro-bumps.

In yet another embodiment of the disclosure, the plurality of semiconductor dies includes a graphic processing unit (GPU) die, a memory die, a logic die, or a combination thereof.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional view of an active interposer structure according to a first embodiment of the disclosure.

FIG. 2 is a plan view of a second transistor in the first embodiment of the disclosure

FIG. 3 is a cross-sectional view of a cross-sectional view of a three-dimensional (3D) IC package according to a second embodiment of the disclosure.

FIG. 4A to FIG. 4D are schematic cross-sectional views of a manufacturing process of an active interposer structure according to a third embodiment of the disclosure.

FIG. 5 is a flowchart of a method associated with forming a silicon FET according to some embodiments of the disclosure.

### DESCRIPTION OF THE EMBODIMENTS

Referring to the embodiments below and the accompanied drawings for a sufficient understanding of the disclosure. These embodiments are described in sufficient detail to enable those skilled in the art to practice the disclosure. However, the disclosure may be implemented in many other different forms and should not be limited to the embodiments described hereinafter. Other embodiments may be utilized and structural, logical, and electrical changes may be made without departing from the scope of the present disclosure. In the drawings, for clarity, the elements and relative dimensions thereof may not be scaled. For easy understanding, the same elements in the following embodiments will be denoted by the same reference numerals.

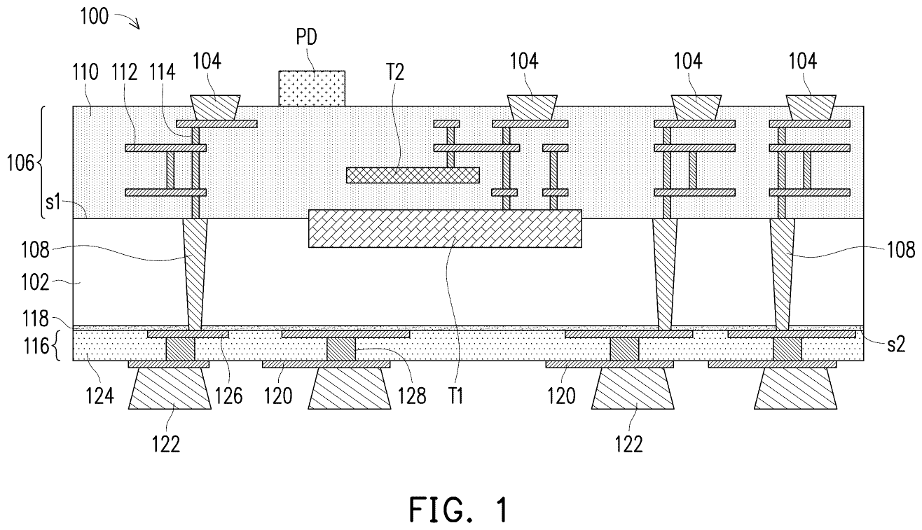

FIG. 1 is a cross-sectional view of an active interposer structure according to a first embodiment of the disclosure.

Referring to FIG. 1, the active interposer structure 100 of the first embodiment includes silicon substrate 102, a first transistor T1, at least one second transistor T2 and micro-bumps (μbumps) 104. The silicon substrate 102 has a first surface s1 and a second surface s2 opposite to the first surface s1. The first transistor T1 is formed on the first surface s1 of the silicon substrate 102. The second transistor T2 is formed over the first transistor T1, wherein the second transistor T2 is different from the first transistor T1. In some embodiments, the first transistor T1 includes a silicon FET, and the second transistor T2 includes a semiconductor layer containing an oxide semiconductor (OS). Since OS FET (OSFET) has extremely low leakage (e.g. <10⁻¹⁹ A), low leakage in the active interposer structure 100 can effectively cut off the current between different chips on the active interposer. In some embodiments, the material of the oxide semiconductor may include gallium oxide (GaOₓ), gallium zinc oxide (Ga₂ZnₓO_{y}) or indium gallium zinc oxide (IGZO). The micro-bumps 104 are formed over the second transistor T2 and electrically connected to the first transistor T1 and the second transistor T2. In some embodiments, a material of the micro-bumps 104 may include copper, CuTi, SnAg, SnCu, SnAgCu, etc.

In some embodiments, a BEOL structure 106 is disposed between the micro-bumps 104 and the silicon substrate 102 for connecting the first transistor T1 and the at least one second transistor T2 to the micro-bumps 104. In some embodiments, the BEOL structure 106 includes an interlayer dielectric (ILD) 110, metal wirings 112, and vias 114. The interlayer dielectric 110 may be a single layer or a multi-layer structure. The metal wirings 112 are disposed in the interlayer dielectric 110, and the vias 114 are connected to the metal wirings 112 above and below thereof.

In some embodiments, through-silicon vias (TSVs) 108 pass through the silicon substrate 102. The TSVs 108 may connect to the BEOL structure 106. In some embodiments, a material of the TSVs 108 may include copper, tantalum, tantalum nitride, or a combination thereof. In some embodiments, a passive device PD may be formed over the second transistor T2, and the passive device PD may be disposed on the micro-bumps 104, wherein the passive device PD, for instance, includes a capacitor, a resistor, or an inductor. In some embodiments, the passive device PD may be electrically connected to the metal wirings 112 of the BEOL structure 106.

In some embodiments, a connection structure 116, a dielectric layer 118, interposer pads 120, and interposer bumps 122 are formed below the silicon substrate 102. The connection structure 116 is formed on the second surface s2 of the silicon substrate 102, and the dielectric layer 118 may be disposed between the connection structure 116 and the silicon substrate 102. In some embodiments, a material of the dielectric layer 118 may include silicon oxide, silicon nitride, or a combination thereof. The interposer pads 120 are disposed on the connection structure 116. The interposer bumps 122 are formed on the interposer pads 120, wherein the interposer bumps 122 may include C4 bumps or the like. In some embodiments, the connection structure 116 includes a dielectric layer 124, redistribution layers 126, and vias 128. The vias 128 connect the redistribution layers 126 to the interposer pads 120. The connection structure 116 may be electrically connected to the BEOL structure 106 through the TSVs 108.

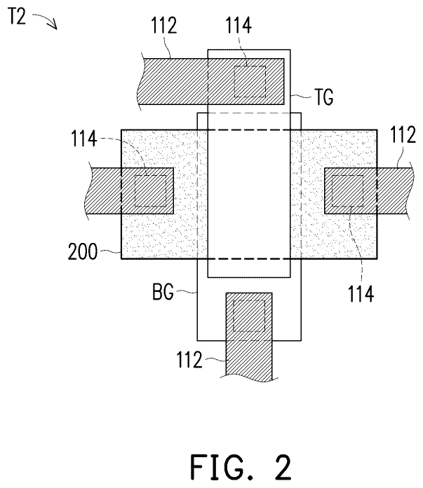

FIG. 2 is a plan view of a second transistor T2 in the first embodiment of the disclosure.

In FIG. 2, the second transistor T2 can be an OS device in which a semiconductor layer 200 contains an oxide semiconductor (OS). The OS device further includes a top gate TG over the semiconductor layer 200, a bottom gate BG below the semiconductor layer 200, and a gate oxide (not shown) between the top gate TG and the semiconductor layer 200. In some embodiments, the material of the gate oxide may include hafnium dioxide (HfO₂), aluminum oxide (Al₂O₃), or the like. The top gate TG and the bottom gate BG may be overlapped each other and have an extension direction different from that of the semiconductor layer 200. The top gate TG and the bottom gate BG may be connect to the metal wiring 112 through different vias 114, and the semiconductor layer 200 at two sides of the top gate TG may be connect to the metal wiring 112 through different vias 114.

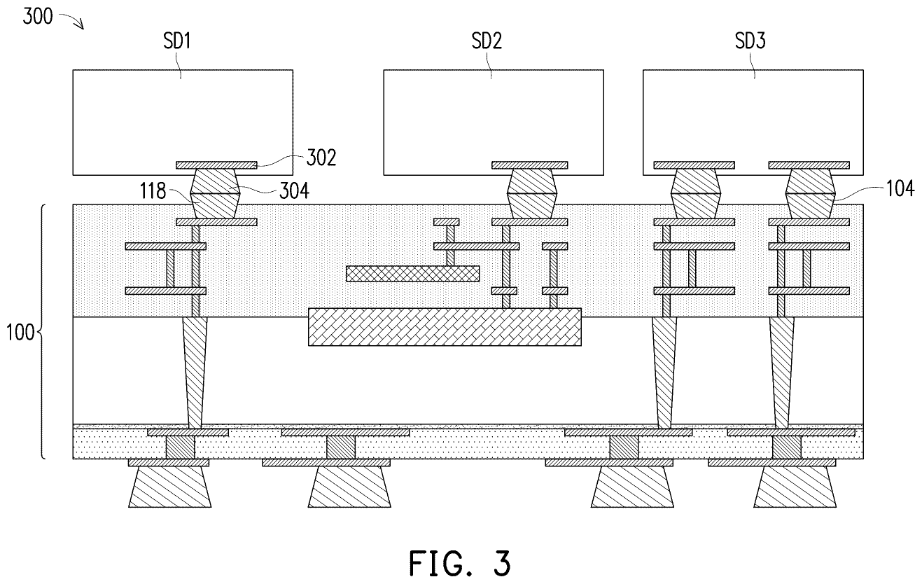

FIG. 3 is a cross-sectional view of a cross-sectional view of a three-dimensional (3D) IC package according to a second embodiment of the disclosure, wherein the same reference numerals as those in the first embodiment are used to indicate the same or similar components, and the content of the same or similar components is also as provided in the content in the first embodiment and is not repeated herein.

As shown in FIG. 3, an 3D IC package 300 includes above active interposer structure 100 and semiconductor dies SD1-SD3. The semiconductor dies SD1-SD3 are bonded to the active interposer structure 100 through the micro-bumps 104. In some embodiments, each of the semiconductor dies SD1-SD3 further includes a metal wiring 302 and connectors 304. In some embodiments, the connectors 304 may include micro-bumps for direct-bonding with the micro-bumps 104. In some embodiments, the semiconductor dies SD1-SD3 may include a graphic processing unit (GPU) die, a memory die, a Logic die, or a combination thereof. For example, the semiconductor die SD1 is a DRAM die, the semiconductor die SD2 is a GPU die, and the semiconductor die SD3 is a Logic die. However, the disclosure is not limited thereto.

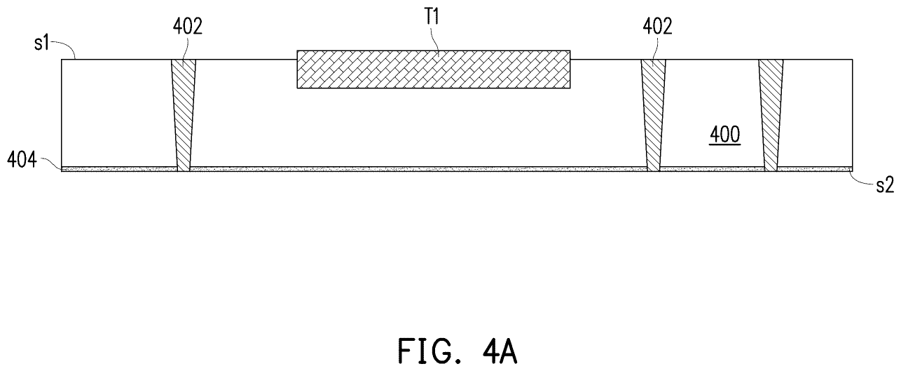

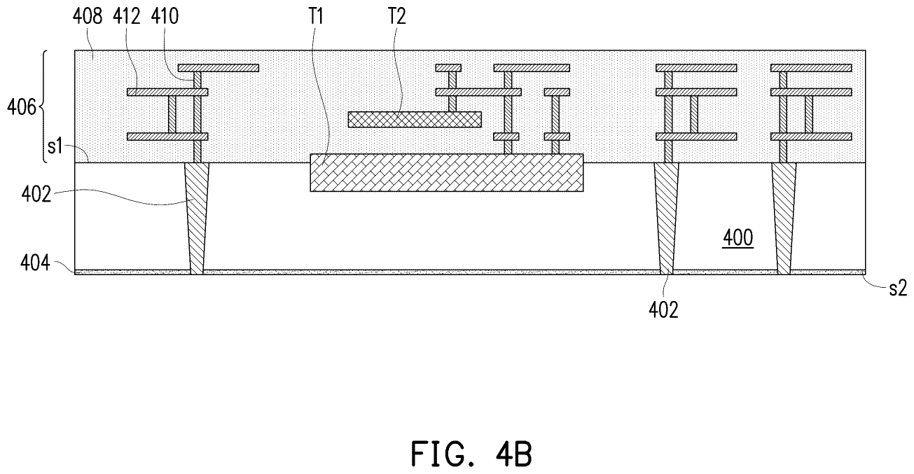

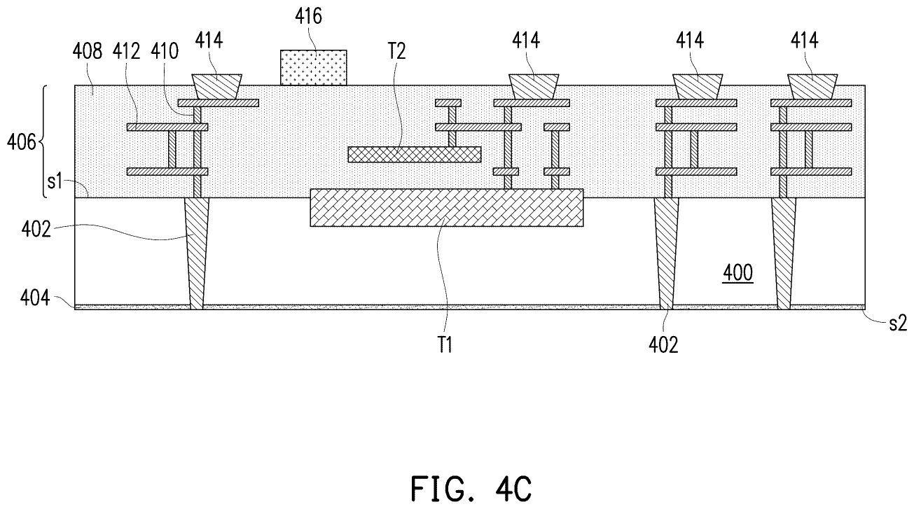

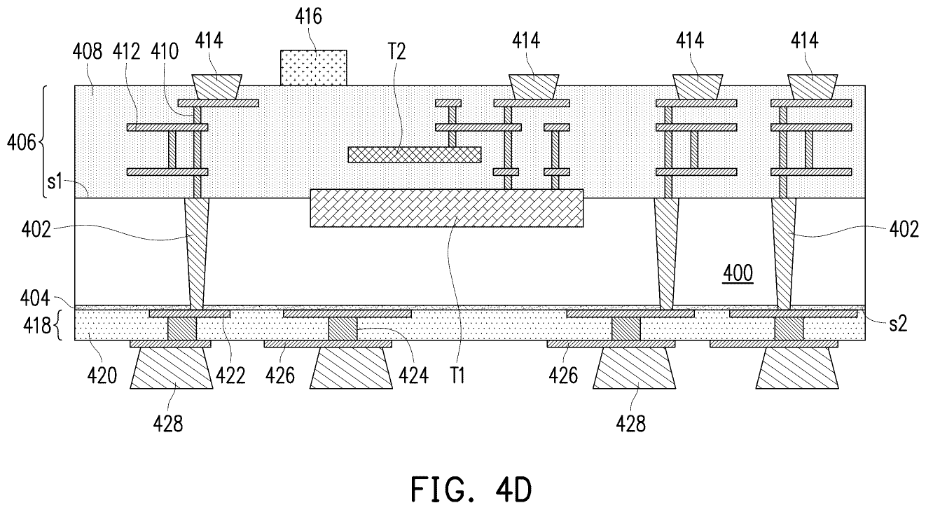

FIG. 4A to FIG. 4D are schematic cross-sectional views of a manufacturing process of an active interposer structure according to a third embodiment of the disclosure.

Referring to FIG. 4A, a first transistor T1 is formed on a first surface s1 of a silicon substrate 400. In some embodiments, the first transistor T1 includes a silicon FET. through-silicon vias (TSVs) 402 may be formed to pass through the silicon substrate 400. In some embodiments, a material of the TSVs 402 may include copper, tantalum, tantalum nitride, or a combination thereof. A dielectric layer 404 may be formed on a second surface s2 of the silicon substrate 400, wherein the second surface s2 is opposite to the first surface s1. In some embodiments, a material of the dielectric layer 404 may include silicon oxide, silicon nitride, or a combination thereof.

Referring to FIG. 4B, at least one second transistor T2 is formed over the first transistor T1. In some embodiments, the second transistor T2 includes a semiconductor layer containing an oxide semiconductor (OS). The second transistor T2 may be formed in a BEOL structure 406. In some embodiments, the method of forming the BEOL structure 406 includes forming one or more interlayer dielectric 408, forming vias 410 in the interlayer dielectric 408, and forming metal wirings 412 in the interlayer dielectric 408, wherein the vias 410 are connected to the metal wirings 412 above and below thereof. In some embodiments, the first transistor T1 and the second transistor T2 can be coupled to the micro-bumps 414 through the BEOL structure 406.

In some embodiments, the method for forming the second transistor T2 may include forming a bottom gate first, forming the semiconductor layer over the bottom gate, forming a gate oxide on the semiconductor layer, and forming a top gate on the gate oxide. The structure of the second transistor T2 can refer to FIG. 2. After that, the vias 410 may be formed to land on the bottom gate, the top gate, and the semiconductor layer, and then the metal wirings 412 are formed to connect to the vias 410. However, the disclosure is not limited thereto. The number of the second transistor T2 may be one or more, and the second transistors T2 are stacked on the first transistor T1.

Referring to FIG. 4C, micro-bumps 414 are formed over the second transistor T2 for coupling to the first transistor T1 and the second transistor T2. In some embodiments, a material of the micro-bumps 414 may include copper, CuTi, SnAg, SnCu, SnAgCu, etc. After forming the micro-bumps 414, a passive device 416 may be formed over the second transistor T2, wherein the passive device 416, for instance, includes a capacitor, a resistor, or an inductor. In some embodiments, the passive device 416 is formed on the micro-bumps 414. However, the disclosure is not limited thereto; in other some embodiments, the passive device 416 may be formed before the formation of the micro-bumps 414, or the passive device 416 is omitted.

Referring to FIG. 4D, a connection structure 418 may be formed on the second surface s2 of the silicon substrate 400. In some embodiments, the method of forming the connection structure 418 includes forming redistribution layers 422 on the dielectric layer 404, forming a dielectric layer 420 on the redistribution layers 422, and forming vias 424 in the dielectric layer 420, wherein the vias 424 are connected to the redistribution layers 422. In some embodiments, The connection structure 418 may be electrically connected to the BEOL structure 406 through the TSVs 402. Interposer pads 426 are formed on the connection structure 418 and connect to the vias 424 of the connection structure 418, and interposer bumps 428 are formed on the interposer pads 426. In some embodiments, the interposer bumps 428 may include C4 bumps or the like.

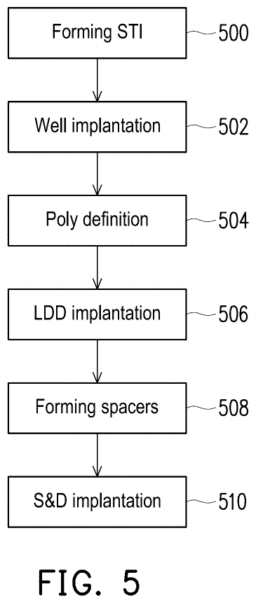

FIG. 5 is a flowchart of a method associated with forming a silicon FET according to some embodiments of the disclosure. For example, the first transistor T1 of above embodiments may be formed as per the process of FIG. 5.

It should be understood that the method shown in FIG. 5 is merely an example of many possible embodiment methods. One of ordinary skill in the art would recognize many variations, alternatives, and modifications. For example, various steps as illustrated in FIG. 8 may be added, omitted, replaced, rearranged and repeated.

Referring to FIG. 5, at block 500, a shallow trench isolation (STI) structure is formed in a silicon substrate to define an active area. At block 502, a well implantation is performed on the silicon substrate to form a well region in the active area. At block 504, a polysilicon layer is formed and defined on the silicon substrate to form a gate, and a gate insulating layer may be formed before the formation of the gate. At block 506, a lightly-doped drain (LDD) implantation is performed on the silicon substrate to form LDD regions in the well region at two sides of the gate. At block 508, spacers are formed on sidewalls of the gate. At block 510, a source/drain (S&D) implantation is performed on the silicon substrate to form source and drain in the well region outside the spacers.

In summary, the interposer according to the disclosure contains active silicon device such as Si transistor and another transistor over the Si transistor, and thus the interposer not only has the function of electrical transmission but also can be configured with different transistors according to needs, thereby applying on different products or 3D IC package.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An active interposer structure, comprising:
a silicon substrate having a first surface and a second surface opposite to the first surface;
a first transistor, formed on the first surface of the silicon substrate;
at least one second transistor, formed over the first transistor, wherein the at least one second transistor is different from the first transistor; and
a plurality of micro-bumps formed over the at least one second transistor and electrically connected to the first transistor and the at least one second transistor.

2. The active interposer structure of claim 1, wherein the first transistor comprises a silicon FET, and the at least one second transistor comprises a semiconductor layer containing an oxide semiconductor.

3. The active interposer structure of claim 1, further comprises a BEOL structure disposed between the plurality of micro-bumps and the silicon substrate for connecting the first transistor and the at least one second transistor to the plurality of micro-bumps.

4. The active interposer structure of claim 1, further comprises a plurality of through-silicon vias passing through the silicon substrate.

5. The active interposer structure of claim 1, further comprises a passive device formed over the at least one second transistor.

6. The active interposer structure of claim 5, wherein the passive device comprises a capacitor, a resistor, or an inductor.

7. The active interposer structure of claim 1, further comprises:
a connection structure formed on the second surface of the silicon substrate;
a plurality of interposer pads disposed on the connection structure; and
a plurality of interposer bumps formed on the plurality of interposer pads.

8. A manufacturing method of an active interposer structure, comprising:
forming a first transistor on a first surface of a silicon substrate;
forming at least one second transistor over the first transistor; and
forming a plurality of micro-bumps over the at least one second transistor for coupling to the first transistor and the at least one second transistor.

9. The manufacturing method of claim 8, wherein before forming the plurality of micro-bumps, further comprises: forming a BEOL structure on the silicon substrate for connecting the first transistor or the at least one second transistor.

10. The manufacturing method of claim 9, wherein the first transistor and the at least one second transistor are coupled to the plurality of micro-bumps through the BEOL structure.

11. The manufacturing method of claim 8, wherein after forming the plurality of micro-bumps, further comprises: forming a passive device over the at least one second transistor.

12. The manufacturing method of claim 8, wherein before forming the at least one second transistor, further comprises: forming a through-silicon vias passing through the silicon substrate.

13. The manufacturing method of claim 8, wherein after forming the plurality of micro-bumps, further comprises:
forming a connection structure on a second surface of the silicon substrate, wherein the second surface is opposite to the first surface;
forming a plurality of interposer pads on the connection structure; and
forming a plurality of interposer bumps on the plurality of interposer pads.

14. The manufacturing method of claim 8, wherein the first transistor comprises a silicon FET, and the at least one second transistor comprises a semiconductor layer containing an oxide semiconductor.

15. A 3D IC package, comprising:
an active interposer structure of claim 1; and
a plurality of semiconductor dies bonded to the active interposer structure through the plurality of micro-bumps.

16. The 3D IC package of claim 15, wherein the plurality of semiconductor dies comprises a graphic processing unit die, a memory die, a logic die, or a combination thereof.
